(19) United States
(12) Patent Application Publication
(10) Pub. No.: US 2009/0032891 A1
(43) Pub. Date: Feb. 5, 2009

(54) STRUCTURE OF MAGNETIC RANDOM ACCESS MEMORY AND FABRICATION METHOD THEREOF

(75) Inventors: Cheng-Tyng Yen, Kaohsiung City (TW); Wei-Chuan Chen, Taipei County (TW); Yung-Hsiang Chen, Hsinchu County (TW); Yung-Hung Wang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/954,217

(22) Filed: Dec. 12, 2007

(30) Foreign Application Priority Data
Jul. 31, 2007 (TW) 96127933

(51) Int. Cl. H01L 29/82; H01L 21/8246

(52) U.S. Cl. 257/421; 438/3; 257/E21.662; 257/E29.323

(57) ABSTRACT

A structure of magnetic random access memory includes a magnetic memory cell formed on a substrate. An insulating layer covers over the substrate and the magnetic memory cell. A write current line is in the insulating layer and above the magnetic memory cell. A magnetic cladding layer surrounds the periphery of the write current line. The magnetic cladding layer includes a first region surrounding the top of the write current line, and a second region surrounding the side edge of the write current line, and extending towards the magnetic memory cell and exceed by a distance.

### CROSS-REFERENCE TO RELATED APPLICATION

This application claims the priority benefit of Taiwan application serial no. 96127933, filed on Jul. 31, 2007. The entirety of the above-mentioned patent application is hereby incorporated by reference herein and made a part of this specification.

### BACKGROUND OF THE INVENTION

1. Field of the Invention

The present invention relates to a structure of magnetic random access memory and fabrication method thereof.

2. Description of Related Art

Magnetic memory, for example Magnetic Random Access Memory (MRAM) is also a nonvolatile memory, having the advantages of non-volatile, highly integrated, high read/write speed, radiation hardened and etc. The magnetic memory uses the relative magnetization orientation of two ferromagnetic layers sandwich with the tunneling barrier layer to store the information, the anti-parallel orientation revealing a higher resistance and parallel orientation revealing a lower resistance corresponding to 1 and 0 states respectively. When data is written in, the usual method is to use two current lines, for example Bit Line (BL) and Write Word Line (WWL). The BL and WWL use induced the magnetic field generated by current to write into the memory cell of magnetic memory selected by intersection. The write method is to change the magnetoresistance value thereof through changing the direction of magnetization in free layer. When reading stored data, current is passed to the selected magnetic memory cell unit, the digital value of the stored data can be determined through the magnetoresistance value that is read out.

FIG. 1 schematically illustrates a basic structure of a magnetic memory cell. With reference to FIG. 1, when accessing a magnetic memory cell, current lines 100, 102 are also needed. The current lines 100, 102 intersect with each other, and proper currents are applied. According to the operation method thereof, the current lines 100, 102 for example may be called write word line and write bit line which are just descriptive words of terms, so as to achieve the respective control of the two dimensional array memory cells.

When current is passed to the two lines, magnetic fields of two directions are generated, so as to obtain the needed magnetic field size and direction to apply on the magnetic memory cell 104. The magnetic memory cell 104 is a layered structure, including a magnetic pinned layer with a fixed magnetization at a predetermined direction, or total magnetic moment, and a magnetic free layer has an alterable magnetization. The value of magnetoresistance is used to read data. Furthermore, through the output electrode 106 and 108, the data stored in the memory cell can be read out. The operation detail of the magnetic memory can be known by those with ordinary skill in the art, therefore will not be further described.

FIG. 2 schematically illustrates the mechanism of magnetic memory. With reference to FIG. 2, the magnetic pinned layer 104a has the magnetic moment direction 107 with a fixed direction. The magnetic free layer 104c is above the magnetic pinned layer 104a, there is an insulation layer 104b in between for separation. The magnetic free layer 104c has a magnetic moment direction 108a or 108b. Since the magnetic moment direction 107 is parallel to the magnetic moment direction 108a, the generated magnetoresistance thereof for example represents data of 0. On the contrary, the magnetic moment direction 107 is anti-parallel to the magnetic moment direction 108b, the generated magnetoresistance thereof for example represents data of 1.

Generally, it is possible that the single-layer free layer 104c as shown in FIG. 2 may have access error. For this problem, in order to reduce the interference of the adjacent cell units when writing data, the improvement method of the prior art is to replace single-layer ferromagnetic material of the free layer with a FM/M/FM three-layer structure, so as to form a magnetic layered free layer 166. The structure thereof is as shown in FIG. 3. The upper layer and lower layer of nonmagnetic metal layer 152 are ferromagnetic metal layers 150, 154 which are arranged in anti-parallel to form close magnetic line of force. The magnetic pinned layer 168 at the bottom is separated from the magnetic layered free layer 166 through a tunneling barrier layer (T) 156. The magnetic pinned layer 168 includes a top pinned (TP) layer 158, a nonmagnetic metal layer 160 and a bottom pinned (BP) layer 162. The TP layer and the BP layer have fixed magnetization. In addition, there is a substrate 164, such as antiferromagneic layer, at the bottom. The antiferromagneic layer provides a coupling exchange field to determine the magnetization direction of the magnetic pinned layer.

For the magnetic free layer 166 with three-layer structure, the write bit line WBL and the write word line WWL are arranged so that the write bit line WBL and the write word line WWL has an including angle of 45 degrees from the magnetic anisotropic axis. The direction of the magnetic anisotropic axis is so called the direction of easy axis. Thus, the bit line BL and the write word line WWL may respectively apply a magnetic field to the free layer 166 in sequence to rotate the magnetization of the free layer 166. The magnetic field includes 45 degrees angle from the easy axis. The data stored in memory cell is determined by two magnetization directions of the ferromagnetic metal layer 154 and the top pined layer 158.

Further, in addition to changing the free layer into a three-layer structure, the prior art also provides an operation mode of toggle mode to rotate the magnetization of the free layer, and to rotate the directions of the two magnetizations of the ferromagnetic metal layers 150, 154. In one write operation, when the two magnetizations directions are turned over once, it represents that the data stored in the memory cell is changed.

The toggle mode operation uses current lines which are perpendicular to each other to apply an operation magnetic field on the selected memory cell. FIG. 4A schematically illustrates a diagram of structural relation of current lines and memory cell of prior art. With reference to FIG. 4A, two current lines 200, 202 are perpendicular to each other, and the intersection thereof is the selected magnetic memory cell 204. The two current lines 200, 202 are also respectively called write bit line and write word line. FIG. 4B schematically illustrates a cross-section structure view of the current lines and memory cell of prior art. Further with reference to FIG. 4B, the magnetic memory cell 204, for example, is the memory cell structure which is previously described. In addition, in order to read magnetoresistance stored in the magnetic memory cell 204, a read line 208 is needed to connect the magnetic memory cell 204 through a via plug. Particularly, such toggle mode operation needs to read stored data before write data in, so as to determine whether or not changing data. In addition, there is an insulation layer 206 exists between the magnetic memory cell 204 and the write word line 202. During operation, current I1 is applied to the write word line 200 to generate a magnetic field at X direction, while current I2 is applied to the write word line 202 to generate a magnetic field at Y direction.

For the above magnetic random access memory of prior art, there is a distance 210 between the write word line 200 and the magnetic memory cell 204. Since the distance 210 is too long, resulting in a large decay in the magnetic field on the magnetic memory cell 204, therefore a stronger write current is required. How to reduce the write current is also a key project that those in the field need to solve initiatively.

### SUMMERY OF THE INVENTION

The present invention provides a structure of magnetic random access memory and fabrication method thereof. The structure can make the operation magnetic field more concentrate on memory cell, so as to reduce the needed current when write.

The present invention provides a structure of magnetic random access memory, including a magnetic memory cell formed on a substrate. An insulation layer covers over the substrate and the magnetic memory cell. A write current line is in the insulation layer, and is above the magnetic memory cell. A magnetic cladding layer is in the insulation layer, and surrounds the write current line. The magnetic cladding layer includes a first region surrounding the top of the write current line; and a second region surrounding a side of the write current line, extending towards the magnetic memory cell and over a distance.

The present invention provided a fabricating method of a magnetic random access memory, including providing a substrate, on which at least a memory cell has been formed. Next, a first insulation layer is formed, in which the first insulation layer covers over the substrate and the magnetic memory cell. A first trench is formed in the first insulation layer, and is above the magnetic memory cell. A write current line is formed in the trench. A second insulation layer is formed over the substrate, and covers over the write current line. A second trench is formed in the first insulation layer and the second insulation layer, and is between the adjacent two magnetic memory cells. A sidewall of the second trench is extending downwards, and is over a side of the write current line by a distance. A magnetic cladding layer cover over an exposed surface of the substrate. A third insulation layer is formed on the magnetic cladding layer.

The present invention further provides a fabricating method of magnetic random access memory, including providing a substrate, on which at least a memory cell has been formed. A first insulation layer covers over the substrate and the magnetic memory cell. A first trench is formed in the first insulation layer, and is above the magnetic memory cell. A write current line is formed in the trench. A second insulation layer is formed over the substrate, and covers the write current line. A magnetic material layer is formed over the second insulation layer. A second trench is formed in the first insulation layer, the second insulation layer and the magnetic material layer, and is between the adjacent two magnetic memory cells. A sidewall of the second trench is extending downwards, and is over a side of the write current line by a distance. A magnetic spacer is formed on the sidewall of the second trench, and contacts the magnetic material layer to form a magnetic cladding layer covering the write current line and the portion of the sidewall extending downwards. A third insulation layer covers over the magnetic material layer and the second trench.

In order to the make the aforementioned and other objects, features and advantages of the present invention comprehensible, a preferred embodiment accompanied with figures is described in detail below.

### BRIEF DESCRIPTIONS OF THE DRAWINGS

FIG. 1 schematically illustrates a basic structure of a magnetic memory cell.

FIG. 2 schematically illustrates the mechanism of a magnetic memory.

FIG. 3 schematically illustrates the cross-section view of the structure of a magnetic memory cell of prior arts.

FIG. 4A schematically illustrates a diagram of structural relation between current lines and memory cell of prior arts.

FIG. 4B schematically illustrates a cross-section structure view of the current lines and memory cell of prior arts.

FIGS. 5-8 schematically illustrate the distribution of a stimulant magnetic line of force formed when a current line is introduced with current according to the embodiment of the present invention.

FIGS. 9A-9H schematically illustrate structural cross-section views of the fabrication flow of magnetic random access memory according to an embodiment of the present invention.

FIGS. 10A-10E schematically illustrate structural cross-section views of the fabrication flow of magnetic random access memory according to another embodiment of the present invention.

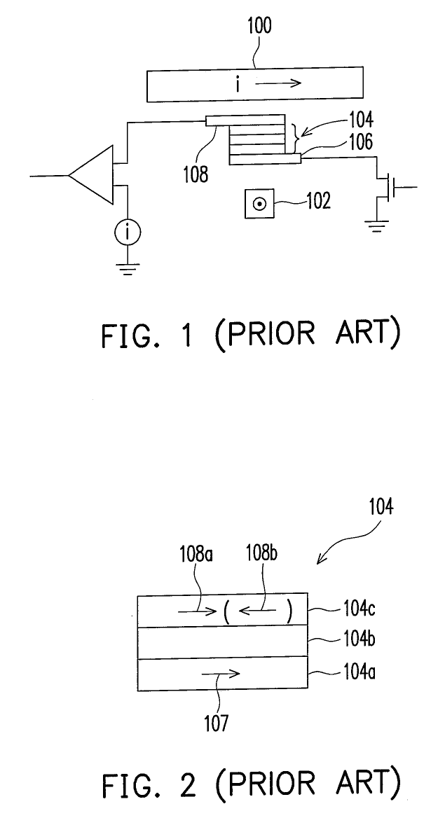

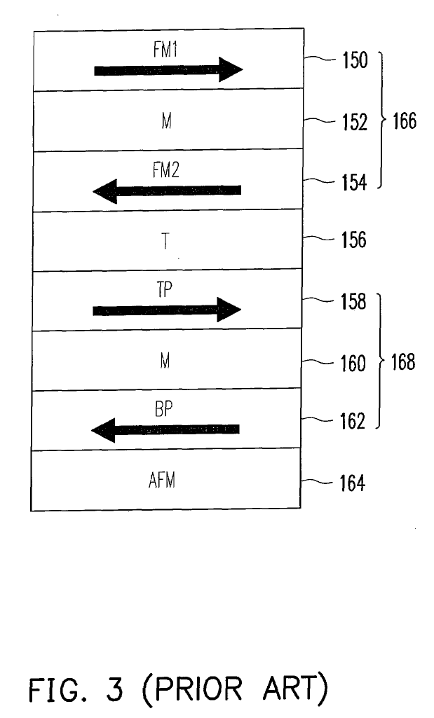

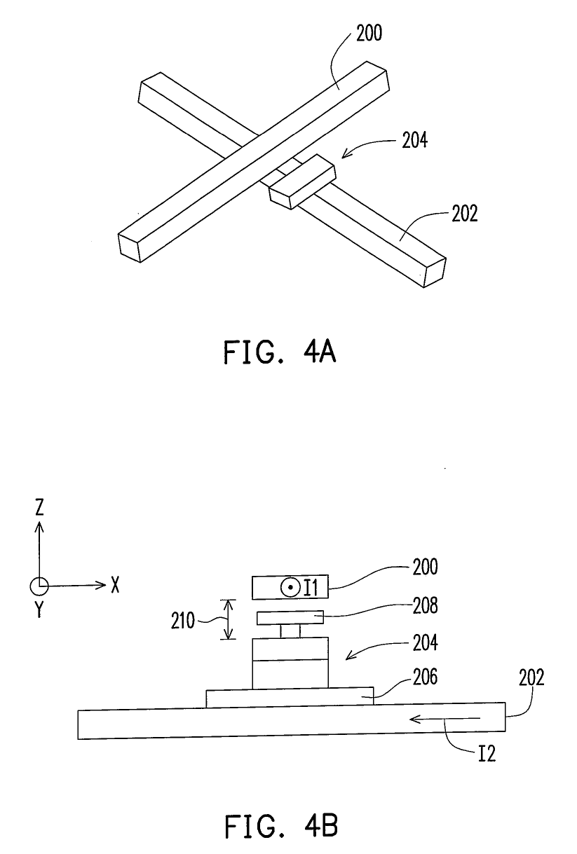

### DESCRIPTION OF EMBODIMENTS

The present invention further proposed that a magnetic cladding layer is formed at the periphery of the write word line to surround the write word line and to extend downwards, so that the magnetic field concentrates more on the magnetic memory cell. For example, the magnetic cladding layer may extend to the read line. Since the operating magnetic field applied on the magnetic memory cell is enhanced, therefore the operation current may be reduced.

The following embodiments are used to describe the present invention, but the present invention is not limited to the exemplary embodiments herein.

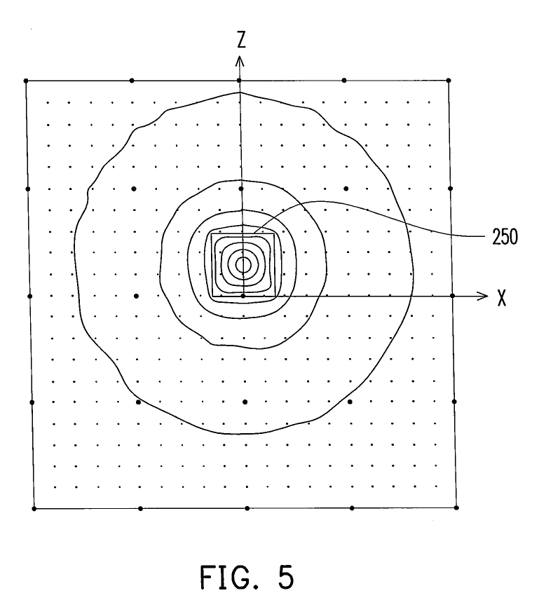

The present invention first discusses the phenomena that the magnetic field generated by the write word line functions on the magnetic memory cell. FIGS. 5-8 schematically illustrate the distribution of magnetic line of force when a current line is applied with current according to the embodiment of the present invention. FIG. 5 shows the result as for the current line of prior art. With reference to FIG. 5, magnetic line of force is generated after a current line 250 is applied with a standard current as for comparison. The origin point of reference coordinate for example is set at the center point of the bottom edge of the current line 250. The magnetic memory cell may be under the current line 250. The intensity of the magnetic field at the place where the magnetic memory cell is located is a phenomenon to be studied and discussed. In the figure, for example the intensity of the magnetic field at the negative direction of Z axis is observed.

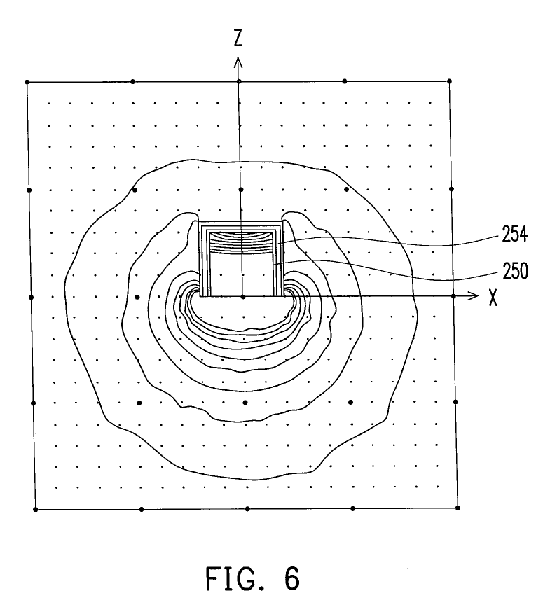

With reference to FIG. 6, a magnetic cladding layer 254 is added to the periphery of the current line 250. The magnetic cladding layer 254 for example only surrounds the top and the side of the current line 250. In this case, since the magnetic cladding layer generates a push and squeeze effect to the magnetic force line, therefore comparing with the situation in FIG. 5, the magnetic field under the current line 250 has an enhanced effect.

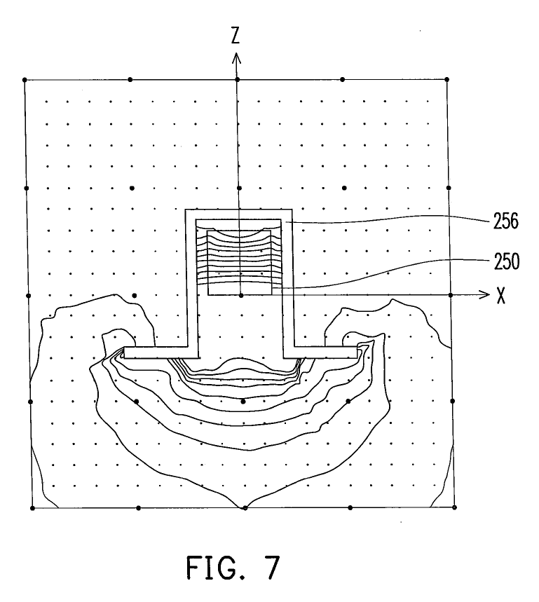

With reference to FIG. 7, a magnetic cladding layer 256 is added to the periphery of the current line 250, and the magnetic cladding layer 256 further extends downwards and exceeds over the current line 250, and further has transverse extending region. In this case, the magnetic field is further effectively concentrated under the current line 250, depending on the length extending downwards. In addition, it can be also seen that there is no obvious increase of magnetic field at the right and left side of the current line 250. This also means that the effect of the magnetic cladding layer 256 does not affect the adjacent regions of the left and right sides. The actual effect is to enhance the magnetic field under the memory cell without actually affect other memory cells.

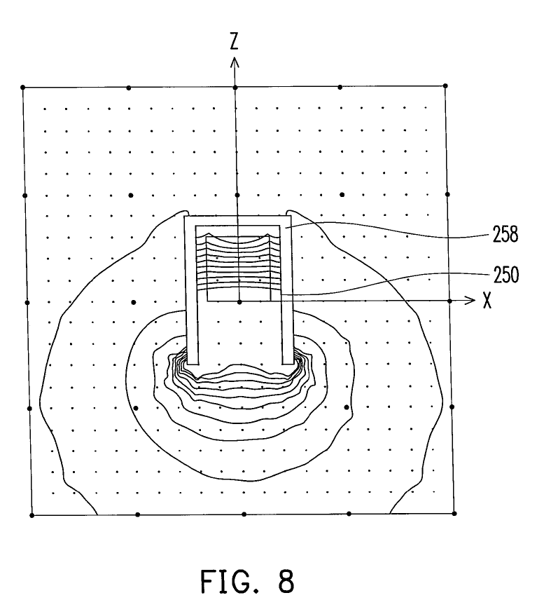

With reference to FIG. 8, the situation is similar to FIG. 7, but there is no transverse extending region under the magnetic cladding layer 258. It is seen according to the distribution of the magnetic flux line, the setting of FIG. 8 also has magnetic field concentration effect, and has less transverse effect.

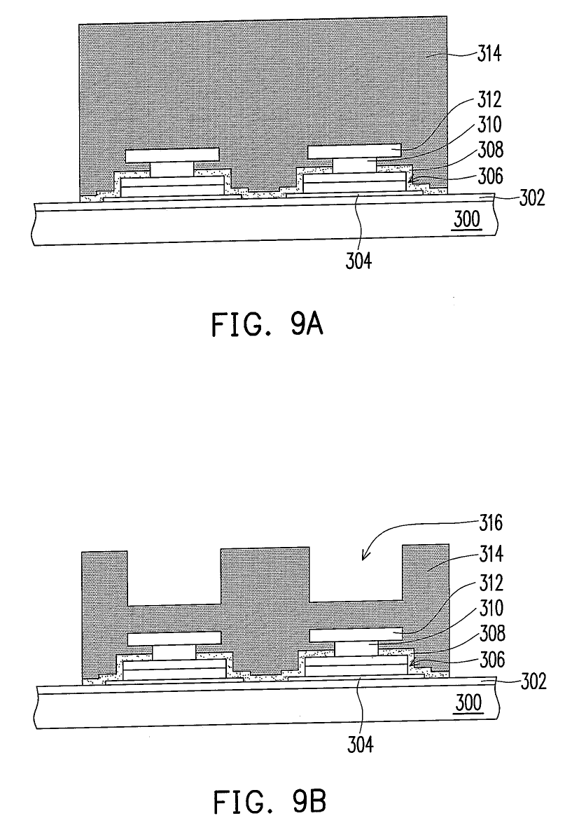

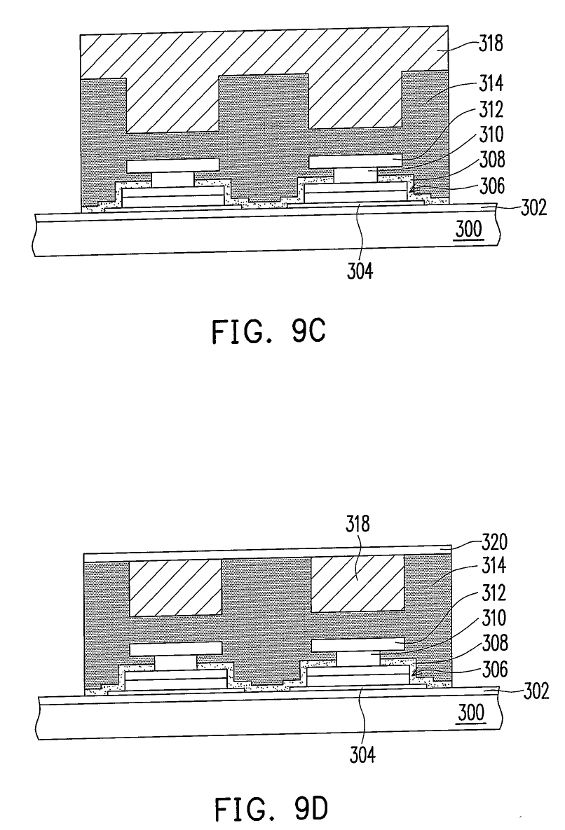

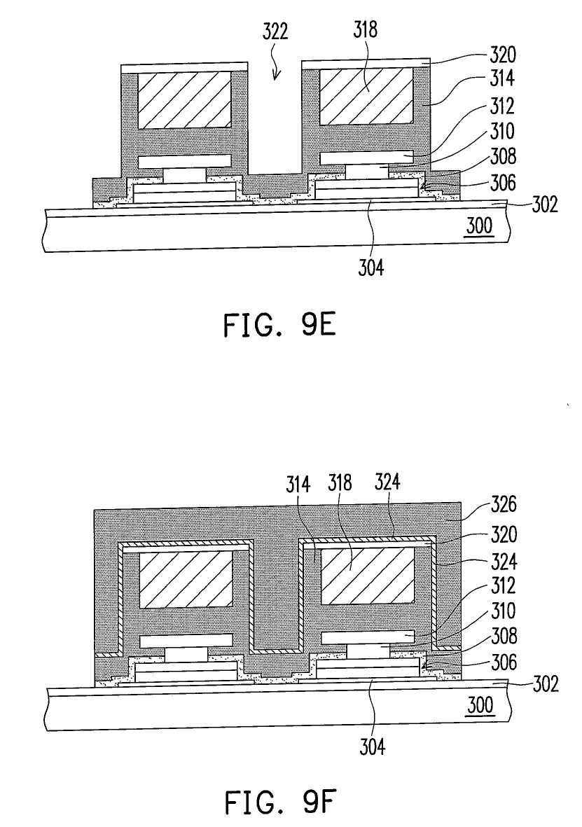

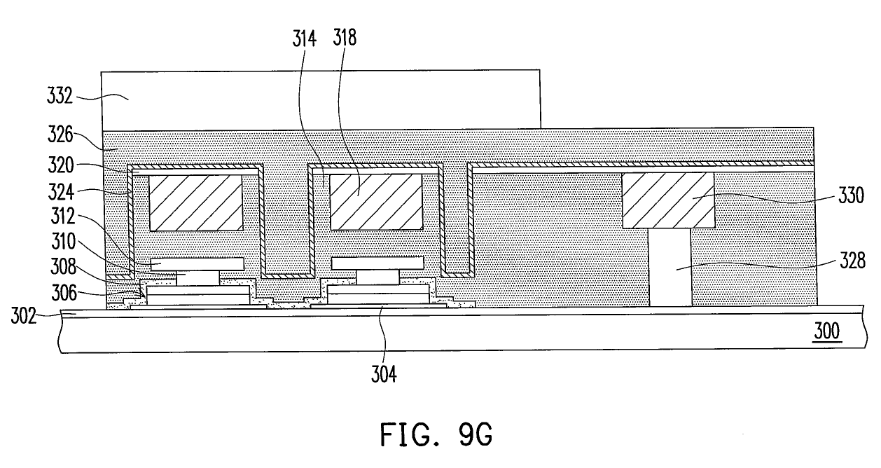

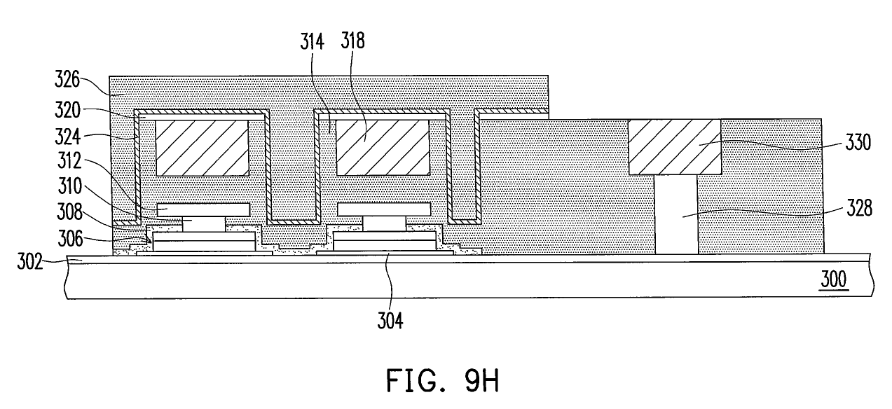

Having discussed the mechanism of the magnetic cladding layer, the present invention proposes a embodiment in design for magnetic random access memory. FIGS. 9A-9H schematically illustrates structural cross-section views of the fabrication flow of magnetic random access memory according to the embodiment of the present invention.

With reference to FIG. 9A, an operation circuit, such as circuit structure including the write word line 302 and the alike, has been formed on a substrate 300. In addition, the magnetic memory cell 306 is also formed over the substrate 300, and is insulated from the write word line 302 through the insulation layer 304. In addition, a protection layer 308 covers over the magnetic memory cell 306, and is connected to the read line 312 by a via plug 310. Next, an insulation layer 314, such as a dielectric layer of silicon oxide, is deposited on the substrate 300 using semiconductor fabricating process, and covers over the memory cell structure on the substrate 300 in the mean time.

With reference to FIG. 9B, for example, photolithographic and etching processes are used to form a trench 316 in the insulation layer 314. The trench 316 is above the magnetic memory cell 306, at the predetermined location to form the write bit line.

With reference to FIG. 9C, a conductive layer 318 is formed on the insulation layer 314 to fill up the trench 316. The material of the conductive layer 318, for example, is copper or other metal, or other material capable of being used as write bit line. With reference to. FIG. 9D, for example, chemical mechanical polishing (CMP) process is used to remove the top portion of the conductive layer 318. Thus the conductive layer 318 filled in the trench 316 acts as the write bit line. Next, an insulation layer 320 is further deposited over the substrate 300 to insulate the exposed conductive layer 318. The material of the insulation layer 320 may be the same as the insulation layer 314 or may be different, such as dielectric material of silicon oxide or silicon nitride, usually.

With reference to FIG. 9E, photolithographic and etching processes are performed to form another trench 322 in the insulation layers 314 and 320. The trench 322 is between the adjacent two magnetic memory cells 306. The sidewall of the trench 322 extends toward the magnetic memory cell 306 and is over the sidewall of the conductive layer 318, such as extending to the read line 312 or even longer. The depth of the trench 322 is determined according to the magnetic cladding layer to be formed later.

With reference to FIG. 9F, a magnetic cladding layer 324 is formed above the substrate 300 to cover an upper surface of the substrate 300. In other words, the magnetic cladding layer 324 may clad the conductive layer 318 and extend towards the magnetic memory cell 306 with the mechanism as described in FIG. 7. The magnetic cladding layer 324, for example, is formed from one layer or multi-layer material, which includes at least a high magnetic permeability soft magnetic material, such as NiFe permalloy. Higher permeability may have more obvious effect. In the present embodiment, the magnetic cladding layer 324 also covers over the horizontal portion of the bottom of the trench 322, so that the magnetic cladding layers 324 at each magnetic memory cells 306 are connected together. Thus, it is convenient in fabrication, and horizontal extending does not affect the operation magnetic field of the adjacent other magnetic memory cells 306. Since there is the insulation layer 320 on the conductive layer 318, the magnetic cladding layer 324 is insulated from the conductive layer 318. In addition, the thickness of the magnetic cladding layer 324 is determined as actually needed. Next, another insulation layer 326 is deposited on the magnetic cladding layers 324, including filling in the trench 322. If a planar surface is needed, then for example, a CMP process is used to planarize the insulation layer 326.

With reference to FIG. 9G, during the process of forming the magnetic memory cell 306 and the subsequent process for the circuits, some other circuits, such as via plug 328, interconnect 330 and so on, may be formed on other regions, such as control circuit region, on the substrate 300. If the insulation layer 320, the magnetic cladding layers 324 and the insulation layer 326 may also cover the control circuit region, they therefore need to be removed. Usually, the photolithographic and etching processes are used to define the insulation layer 320, the magnetic cladding layers 324 and the insulation layer 326. Firstly, photoresist 332 is formed on the insulation layer 326 by photolithographic process, and then the photoresist 322 is patterned to cover the portion, which would remain. For example, the memory region having the magnetic memory cell 306 is covered.

With reference to FIG. 9H, the photoresist 332 is used as the etching mask to remove the exposed portion of the insulation layer 320, the magnetic cladding layers 324 and the insulation layer 326 by etching, such as reactive ion etching.

The above process may be completed using usual fabrication process for semiconductor device. The details thereof will not be described herein.

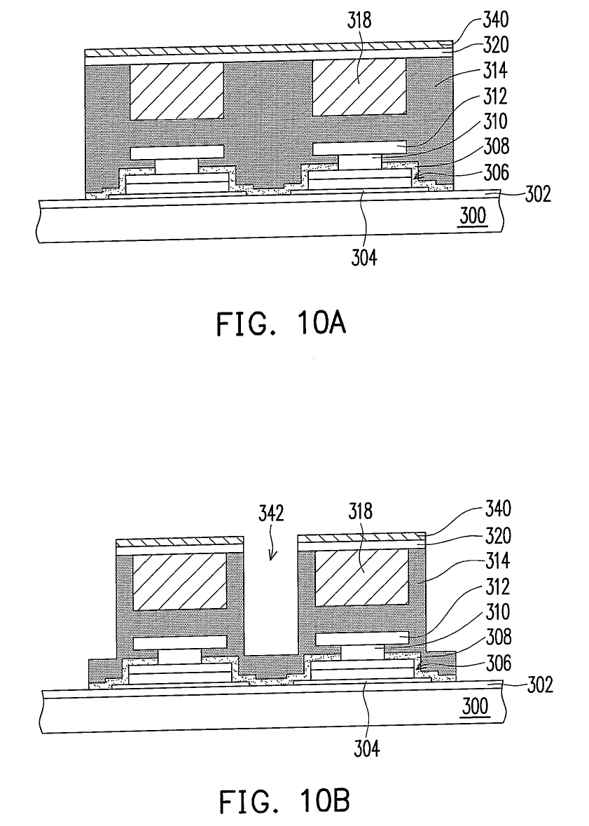

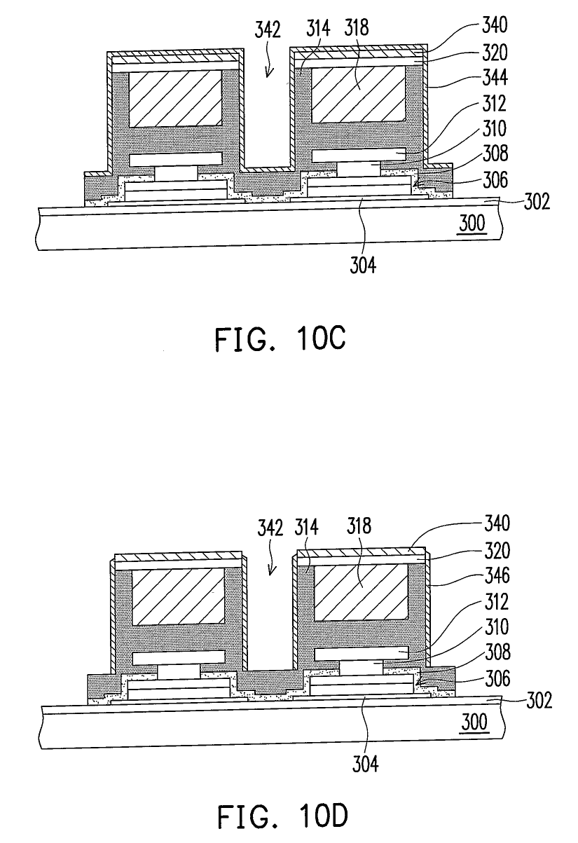

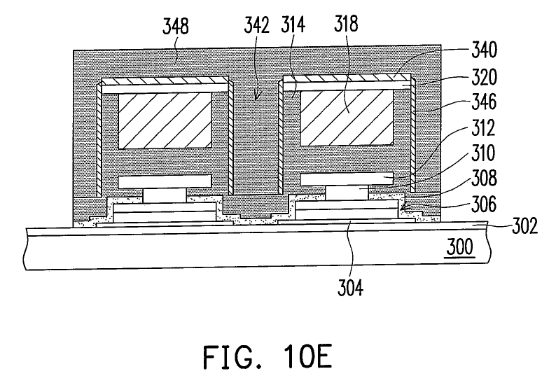

In addition, if the magnetic cladding layer 324 is designed according to the mechanism of FIG. 8, then the first portion of the process is the same as FIGS. 9A-9D. FIGS. 10A-10E schematically illustrate structural cross-section views of the fabricating flow of magnetic random access memory according to another embodiment of the present invention. After the process of FIG. 9D, with reference to FIG. 10A, first, a magnetic material layer 340 is deposited. The material thereof, for example, is the same as the material of the magnetic cladding layer 324 that is previously described, but may also be different. After the subsequent process is finished, the remaining portion of the magnetic material layer 340 may serves as a portion of the magnetic cladding layer.

With reference to FIG. 10B, photolithographic and etching processes are used to define the magnetic material layer 340, the insulation layer 320 and the insulation layer 314, so as to form the trench 342. The trench 342 is between the adjacent two magnetic memory cells 306.

With reference to FIG. 10C, next, another magnetic material layer 344 is further deposited to form over the substrate 300 to cover the structural surface of the substrate 300. The magnetic material layer 340 and the magnetic material layer 344, for example, are made of the same material which has high permeability, such as NiFe or other appropriate material. Further, the material of the magnetic material layer 340 and the magnetic material layer 344 may also be different.

With reference to FIG. 10D, an etching back process is performed to remove the magnetic material layer 344 at the bottom of the trench 342. In the mean time, the magnetic material layer 344 on the magnetic material layer 340 is removed by approximately the same thickness. However, since the magnetic material layer 340 has been formed earlier, therefore the magnetic material layer 340 will still remain, and the residual part of the magnetic material layer 344 forms the spacer 346 on the sidewall of the trench 342. The spacer 346 and the magnetic material layer 340 form the magnetic cladding layer as intended. However, in the present embodiment, the adjacent magnetic cladding layers are not connected to each other. The spacer 346 is extending towards the magnetic memory cell 306 for an appropriate length, so that the magnetic field is more concentrated on the magnetic memory cell 306.

With reference to FIG. 10E, next, an insulation layer 348 is further formed by deposition to fill in the trench 342. Similar to FIGS. 9G-9H, some unwanted portions are removed at the circuit region. For the structure, the magnetic cladding layer formed form the spacer 346 and the magnetic material layer 340 is similar to the magnetic cladding layer 324 of FIG. 9F, the difference is that the adjacent magnetic cladding layers are not connected to each other.

The present invention forms trench between write bit lines, and fills the trench with a soft magnetic material metal layer which has high permeability to serve as the cladding layer. The cladding layer can avoid divergence of the magnetic field being caused when current is passed to write bit line. Therefore, the efficiency of converting write current into write magnetic field is increased, so that the current needed when writing to memory unit is reduced, and the goal of saving electricity is achieved. Moreover, when current is passed to write bit line, the interference to the adjacent write bit line can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed:

1. A magnetic random access memory structure, comprising:
a magnetic memory cell, formed on a substrate;
an insulation layer, covering over the substrate and the magnetic memory cell;
a write current line, in the insulation layer, and above the magnetic memory cell; and
a magnetic cladding layer, in the insulation layer, surrounding a periphery of the write current line, wherein a first region of the magnetic cladding layer surrounds above the write current line, a second region of the magnetic cladding layer surrounds a side edge of the write current line, extending towards the magnetic memory cell and exceeding over by a length.

2. The magnetic random access memory structure of claim 1, wherein the first region and the second region of the magnetic cladding layer are two different structure layers in contact.

3. The magnetic random access memory structure of claim 1, wherein the magnetic cladding layer only clads the write current line corresponding to the magnetic memory cell.

4. The magnetic random access memory structure of claim 1, wherein the magnetic cladding layer clads the corresponding magnetic memory cell, and further continuously clads the write current line of the adjacent magnetic memory cell.

5. The magnetic random access memory structure of claim 1, wherein the first region and the second region of the magnetic cladding layer are the same structure layer.

6. The magnetic random access memory structure of claim 5, wherein the second region further comprises an extension region to connect to the magnetic cladding layer of the corresponding adjacent magnetic memory cell.

7. The magnetic random access memory structure of claim 1, wherein the second region of the magnetic cladding layer at least extends to the magnetic memory cell.

8. The magnetic random access memory structure of claim 7, wherein the second region of the magnetic cladding layer at least extends to a read line of the magnetic memory cell.

9. The magnetic random access memory structure of claim 1, wherein the magnetic cladding layer has sufficient magnetic permeability.

10. The magnetic random access memory structure of claim 1, wherein the write current line generates a magnetic field when an operation current is introduced, and the magnetic cladding layer concentrates the magnetic field generated by the operation current on the magnetic memory cell.

11. A fabrication method of magnetic random access memory, comprising:
providing a substrate, at least a magnetic memory cell having been formed on the substrate;
forming a first insulation layer, covering over the substrate and the magnetic memory cell;
forming a first trench in the first insulation layer, above the magnetic memory cell;
forming a write current line in the trench;
forming a second insulation layer above the substrate, and covering over the write current line;
forming a second trench in the first insulation layer and the second insulation layer, between the adjacent two magnetic memory cells, wherein a sidewall of the second trench extends downwards, and exceeds over a side edge of the write current line by a length;
forming a magnetic cladding layer, covering over an exposed surface of the substrate; and
forming a third insulation layer on the magnetic cladding layer.

12. The fabrication method of magnetic random access memory of claim 11, wherein in the step of forming the second trench, the sidewall of the second trench at least extends to the magnetic memory cell.

13. The fabrication method of magnetic random access memory of claim 11, wherein in the step of forming the second trench, the sidewall of the second trench at least extends to a read line of the magnetic memory cell.

14. The fabrication method of magnetic random access memory of claim 11, wherein a material of the magnetic cladding layer has sufficient magnetic permeability.

15. The fabrication method of magnetic random access memory of claim 11, wherein the first insulation layer, the second insulation layer and the third insulation layer are made of same or different dielectric materials.

16. The fabrication method of magnetic random access memory of claim 11, further comprising removing the third insulation layer, the magnetic cladding layer and the second insulation layer at unwanted portion other than a magnetic memory cell array.

17. A fabrication method of magnetic random access memory, comprising:
providing a substrate, at least a magnetic memory cell having been formed on the substrate.
forming a first insulation layer, covering over the substrate and the magnetic memory cell.
forming a first trench in the first insulation layer, above the magnetic memory cell;
forming a write current line in the first trench;
forming a second insulation layer above the substrate, and covering the write current line;
forming a magnetic material layer on the second insulation layer;
forming a second trench in the first insulation layer, the second insulation layer and the magnetic material layer, and between the adjacent two magnetic memory cells, wherein a sidewall of the second trench extends downwards, and exceeds over a side edge of the write current line by a length;
forming a magnetic spacer on the sidewall of the second trench, and contacting the magnetic material layer to form a magnetic cladding layer covering over the write current line and a downwards extending portion of the sidewall; and
forming a third insulation layer, covering over the magnetic material layer and the second trench.

18. The fabrication method of magnetic random access memory of claim 17, wherein in the step of forming the second trench, the sidewall of the second trench at least extends to the magnetic memory cell.

19. The fabrication method of magnetic random access memory of claim 17, wherein in the step of forming the second trench, the sidewall of the second trench at least extends to a read line of the magnetic memory cell.

20. The fabrication method of magnetic random access memory of claim 17, wherein a material of the magnetic cladding layer has sufficient magnetic permeability.

21. The fabrication method of magnetic random access memory of claim 17, wherein the first insulation layer, the second insulation layer and the third insulation layer are made of same or different dielectric materials.

22. The fabrication method of the magnetic random access memory of claim 17, wherein the step of forming the magnetic spacer comprises:
forming a magnetic material layer, covering over a structural surface of the substrate; and
performing an etching back process, to remove a portion of the magnetic material layer, and to a remaining portion forms the magnetic spacer.

23. The fabrication method of the magnetic random access memory of claim 17, further comprising removing an unwanted portion of the third insulation layer, the magnetic cladding layer and the second insulation layer, other than the magnetic memory cell.
